(19) United States
(12) Patent Application Publication
(10) Pub. No.: US 2009/0212015 A1
(43) Pub. Date: Aug. 27, 2009

(54) Plasma-Assisted Processing in a Manufacturing Line

(76) Inventors: Mike L. Dougherty, SR., Rochester Hills, MI (US); Devendra Kumar, Rochester Hills, MI (US); Satyendra Kumar, Troy, MI (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 11/886,596

(22) PCT Filed: Mar. 17, 2006
(86) PCT No.: PCT/US2006/009753

§ 371 Date: Jan. 8, 2009

Related U.S. Application Data
(60) Provisional application No. 60/663,295, filed on Mar. 18, 2005.

(51) Int. Cl. B44C 1/22; H05H 1/24; B32B 37/00; C23C 16/54; C23F 1/08

(52) U.S. Cl. 216/67; 427/569; 156/272.2; 118/723 R; 156/345.51; 156/379.6

(57) ABSTRACT

Methods and apparatus are provided for plasma-assisted processing multiple work pieces in a manufacturing line. The manufacturing line can include a plurality of microwave cavities, each of the microwave cavities igniting and sustaining a microwave plasma. Work pieces can be shuttled between the plurality of microwave cavities on a conveyance system that controls the positioning of each of the work pieces.

### CROSS-REFERENCE OF RELATED APPLICATIONS

This application is a continuation-in-part of U.S. application Ser. No. 10/513,605, filed on Nov. 5, 2004, claiming priority to PCT Application Serial No. PCT/US03/14055, filed on May 7, 2003, darning priority to U.S. Provisional Patent Application No. 60/378,693, filed May 8, 2002, No. 60/430,677, filed Dec. 4, 2002, and No. 60/435,278, filed Dec. 23, 2002, all of which are fully incorporated herein by reference. This application further claims priority to U.S. Provisional Application 60/663,295, filed on Mar. 18, 2005, which is also herein incorporated by reference in its entirety.

### FIELD OF THE INVENTION

This invention relates to methods and apparatus for plasma-assisted processing of work pieces in a manufacturing line.

### BACKGROUND OF THE INVENTION

Plasmas can be used to assist in a number of processes, including the joining and heat-treating of materials. However, igniting, modulating, and sustaining plasmas for these purposes can be difficult for a number of reasons.

For example, it is known that a plasma can be ignited in a cavity by directing a large amount of microwave radiation into the cavity containing a gas. If the radiation intensity is large enough, the plasma can ignite spontaneously. However, radiation sources capable of supplying such large intensities can have several disadvantages; they can be expensive, heavy, bulky, and energy-consuming. Moreover, these large radiation sources normally require large electrical power supplies, which can have similar disadvantages.

One way of igniting a plasma with a lower radiation intensity is to reduce the pressure in the cavity. However, vacuum equipment, which can be used to reduce this pressure, can limit manufacturing flexibility, especially as the plasma chambers become large and especially in the context of manufacturing lines.

A sparking device can also be used to ignite a plasma using a lower radiation intensity. Such a device, however, only sparks periodically and therefore can only ignite a plasma periodically, sometimes causing an ignition lag. Moreover, conventional sparking devices are normally powered with electrical energy, limiting their use and position in many manufacturing environments.

### BRIEF SUMMARY OF A FEW ASPECTS OF THE INVENTION

A method of plasma-assisted processing of a plurality of work pieces can be provided. In one embodiment, a method of plasma-assisted processing a plurality of work pieces is provided. A method of plasma-assisted processing a plurality of work pieces can include placing each of the plurality of work pieces in a plurality of movable carriers; moving a first subset of movable carriers into a first irradiation zone with a conveyance system; flowing a gas into the first irradiation zone; igniting the gas in the first irradiation zone to form a first plasma; sustaining the first plasma for a period of time sufficient to at least partially plasma process work pieces in the first subset of movable carriers in the first irradiation zone; removing the first subset of movable carriers out of the first irradiation zone with the conveyance system; moving a second subset of movable carriers into a second irradiation zone with the conveyance system; and processing the second subset of movable carriers with a second plasma ignited in the second irradiation zone. In some embodiments, the first subset of movable carriers is processed in the first irradiation zone concurrently with processing the second subset of movable carriers in the second irradiation zone. In some embodiments, the first subset of movable carriers is identical with the second subset of movable carriers. In some embodiments, the plasma-processing is at least one of sintering, annealing, normalizing, spheroiding, tempering, age hardening, case hardening, joining, doping, nitriding, carburizing, decrystallizing, carbo-nitriding, cleaning, sterilizing, vaporizing, coating and ashing.

An apparatus for plasma-assisted processing a plurality of work pieces according to the present invention can include a first chamber, the first chamber coupled to receive a gas flow and radiation in order to ignite a first plasma within the first chamber; a second chamber, the second chamber coupled to receive a gas flow and radiation in order to ignite a second plasma within the second chamber; and a conveyance system coupled to shuttle work pieces in and out of each of the first chamber and the second chamber. Each of the chambers can include a plurality of magnetrons to provide microwave power. In some embodiments, a chamber can include microwave absorbers positioned to maximize the microwave energy at a cavity. In some embodiments a chamber can include more than one cavity.

Additional plasma catalysts, and methods and apparatus for igniting, modulating, and sustaining a plasma for producing a gas consistent with this invention are also provided.

### BRIEF DESCRIPTION OF THE DRAWINGS

Further aspects of the invention will be apparent upon consideration of the following detailed description, taken in conjunction with the accompanying drawings, in which like reference characters refer to like parts throughout, and in which:

FIG. 1 shows a schematic diagram of an illustrative plasma-assisted gas production system consistent with this invention;

FIG. 1A shows an illustrative embodiment of a portion of a plasma-assisted gas production system for adding a powder plasma catalyst to a plasma cavity for igniting, modulating, or sustaining a plasma in a cavity consistent with this invention;

FIG. 2 shows an illustrative plasma catalyst fiber with at least one component having a concentration gradient along its length consistent with this invention;

FIG. 3 shows an illustrative plasma catalyst fiber with multiple components at a ratio that varies along its length consistent with this invention;

FIG. 4 shows another illustrative plasma catalyst fiber that includes a core under layer and a coating consistent with this invention;

FIG. 5 shows a cross-sectional view of the plasma catalyst fiber of FIG. 4, taken from line 5-5 of FIG. 4, consistent with this invention;

FIG. 6 shows an illustrative embodiment of another portion of a plasma system including an elongated plasma catalyst that extends through ignition port consistent with this invention;

FIG. 7 shows an illustrative embodiment of an elongated plasma catalyst that can be used in the system of FIG. 6 consistent with this invention;

FIG. 8 shows another illustrative embodiment of an elongated plasma catalyst that can be used in the system of FIG. 6 consistent with this invention;

FIG. 9 shows an illustrative embodiment of a portion of a plasma-assisted processing system for directing ionizing radiation into a radiation chamber consistent with this invention;

FIG. 10 shows a perspective view of illustrative apparatus for plasma-assisted processing of multiple work pieces consistent with this invention;

FIG. 11 shows another perspective view of the illustrative apparatus of FIG. 10 consistent with this invention;

FIG. 12 shows a top plan view of an illustrative conveyor that can be used with the apparatus of FIG. 10 consistent with this invention;

FIG. 13 shows a cross-sectional view of the illustrative conveyor of FIG. 12, taken along line 13-13 of FIG. 12, along with various additional components and work pieces, consistent with this invention;

FIG. 14 shows a cross-sectional view of another illustrative conveyor with recesses in which work pieces can be placed consistent with this invention; and

FIG. 15 shows a flow-chart for an illustrative method of plasma-processing a plurality of work pieces consistent with this invention.

FIG. 16 illustrates a multi-chamber processing system according to the present invention.

FIGS. 17A through 17C illustrates aspects of the multi-chamber processing system illustrated in FIG. 16.

FIGS. 18A through 18D illustrate further aspects of the multi-chamber processing system illustrated in FIG. 16.

FIG. 19 illustrates an embodiments of a control system that can be utilized with the multi-chamber processing system illustrated in FIG. 16.

FIGS. 20A through 20D illustrate a chamber that can be utilized with the multi-chamber processing system according to the present invention.

FIG. 21 illustrates another multi-chamber processing system according to some embodiments of the present invention.

FIG. 22 illustrates another multi-chamber processing system according to some embodiments of the present invention.

FIG. 23 illustrates a reactor assembly that can be utilized in multi-chamber processing systems according to embodiments of the present invention.

FIG. 24 illustrates in more detail the reactor system shown in FIG. 22 according to some embodiments of the present invention.

### DETAILED DESCRIPTION OF THE EMBODIMENTS

This invention relates to methods and apparatus for plasma-assisted processing in a manufacturing line and can be used to lower energy costs and increase manufacturing flexibility.

The following commonly owned, concurrently filed U.S. patent applications are hereby incorporated by reference in their entireties: Kumar et al. U.S. patent application Ser. No. 10/513,221 (Atty. Docket No. 1837.0008), U.S. patent application Ser. No. 10/513,393 (Atty. Docket No. 1837.0009), PCT Application PCT/US03/14132 (Atty. Docket No. 1837.0010, now abandoned), U.S. patent application Ser. No. 10/513,394 (Atty. Docket No. 1837.0011), U.S. patent application Ser. No. 10/513,305 (Atty. Docket No. 1837.0012), U.S. patent application Ser. No. 10/513,607 (Atty. Docket No. 1837.0013), U.S. Pat. No. 6,870,124 (Atty. Docket No. 1837.0015), PCT Application No. PCT/US03/14034 (Atty. Docket No. 1837.0016, now abandoned), U.S. patent application Ser. No. 10/430,416 (Atty. Docket No. 1837.0017), U.S. patent application Ser. No. 10/430,415 (Atty. Docket No. 1837.0018), PCT Application No. PCT/US03/14133 (Atty. Docket No. 1837.0020, now abandoned), U.S. patent application Ser. No. 10/513,606 (Atty. Docket No. 1837.0021), U.S. patent application Ser. No. 10/513,309 (Atty. Docket No. 1837.0023), U.S. patent application Ser. No. 10/513,220 (Atty. Docket No. 1837.0024), PCT Application No. PCT/US03/14122 (Atty. Docket No. 1837.0025, now abandoned), U.S. patent application Ser. No. 10/513,397 (Atty. Docket No. 1837.0026), PCT Application No. PCT/US03/14137 (Atty. Docket No. 1837.0028, now abandoned), U.S. patent application Ser. No. 10/430,426 (Atty. Docket No. 1837.0029), PCT Application No. PCT/US03/14121 (Atty. Docket No. 1837.0030, now abandoned), U.S. patent application Ser. No. 10/513,604 (Atty. Docket No. 1837.0032), and PCT Application No. PCT/US03/14135 (Atty. Docket No. 1837.0033).

Illustrative Plasma System

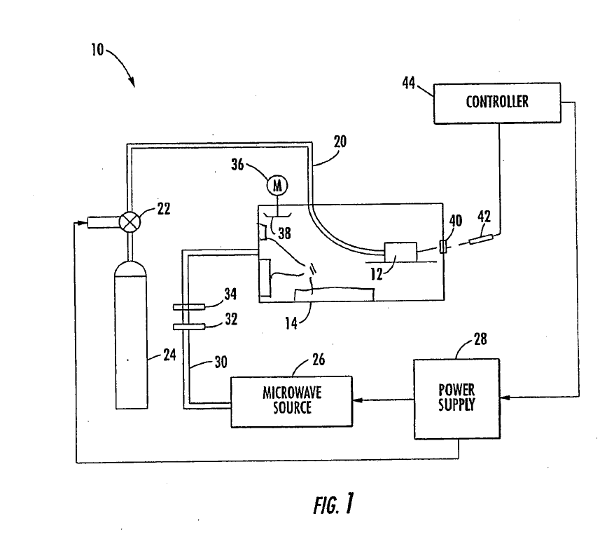

FIG. 1 shows illustrative plasma system 10 consistent with one aspect of this invention. In this embodiment, cavity 12 is formed in a vessel that is positioned inside radiation chamber (i.e., applicator) 14. In another embodiment (not shown), vessel 12 and radiation chamber 14 are the same, thereby eliminating the need for two separate components. The vessel in which cavity 12 is formed can include one or more radiation-transmissive insulating layers to improve its thermal insulation properties without significantly shielding cavity 12 from the radiation. As described more fully below, system 10 can be used to generate a plasma and can be included in a manufacturing line consistent with this invention.

In one embodiment, cavity 12 is formed in a vessel made of ceramic. Due to the extremely high temperatures that can be achieved with plasmas consistent with this invention, a ceramic capable of operating at about 3,000 degrees Fahrenheit can be used. The ceramic material can include, by weight, 29.8% silica, 68.2% alumina, 0.4% ferric oxide, 1% titania, 0.1% lime, 0.1% magnesia, 0.4% alkalies, which is sold under Model No. LW-30 by New Castle Refractories Company, of New Castle, Pa. It will be appreciated by those of ordinary skill in the art, however, that other materials, such as quartz, and those different from the one described above, can also be used consistent with the invention.

In one successful experiment, a plasma was formed in a partially open cavity inside a first brick and topped with a second brick. The cavity had dimensions of about 2 inches by about 2 inches by about 1.5 inches. At least two holes were also provided in the brick in communication with the cavity: one for viewing the plasma and at least one hole for providing the gas. The size of the cavity can depend on the desired plasma process being performed. Also, the cavity can at least be configured to prevent the plasma from rising/floating away from the primary processing region.

Cavity 12 can be connected to one or more gas sources 24 (e.g., a source of argon, nitrogen, hydrogen, xenon, krypton) by line 20 and control valve 22, which may be powered by power supply 28. Line 20 may be tubing (e.g., between about 1/16 inch and about ¼ inch, such as about 1/8″), but could be any device capable of delivering gas. Also, if desired, a vacuum pump can be connected to the chamber to remove fumes that may be generated during plasma processing. In one embodiment, gas can flow in and/or out of cavity 12 through one or more gaps in a multi-part vessel. Thus, gas ports consistent with this invention need not be distinct holes and can take on other forms as well, such as many small distributed holes.

A radiation leak detector (not shown) was installed near source 26 and waveguide 30 and connected to a safety interlock system to automatically turn off the radiation (e.g., microwave) power supply if a leak above a predefined safety limit, such as one specified by the FCC and/or OSHA (e.g., 5 mW/cm²), was detected.

Radiation source 26, which may be powered by electrical power supply 28, can direct radiation energy into chamber 14 through one or more waveguides 30 or by using a coaxial cable. It will be appreciated by those of ordinary skill in the art that source 26 can be connected directly to cavity 12 or chamber 14, thereby eliminating waveguide 30. The radiation energy entering cavity 12 is used to ignite a plasma within the cavity. This plasma can be substantially sustained and confined to the cavity by coupling additional radiation with the catalyst.

Radiation energy can be supplied through circulator 32 and tuner 34 (e.g., 3-stub tuner). Tuner 34 can be used to minimize the reflected power as a function of changing ignition or processing conditions, especially after the plasma has formed because microwave power, for example, will be strongly absorbed by the plasma.

As explained more fully below, the location of radiation-transmissive cavity 12 in chamber 14 may not be critical if chamber 14 supports multiple modes, and especially when the modes are continually or periodically mixed. As also explained more fully below, motor 36 can be connected to mode-mixer 38 for making the time-averaged radiation energy distribution substantially uniform throughout chamber 14. Furthermore, window 40 (e.g., a quartz window) can be disposed in one wall of chamber 14 adjacent to cavity 12, permitting temperature sensor 42 (e.g., an optical pyrometer) to be used to view a process inside cavity 12. In one embodiment, the optical pyrometer output can increase from zero volts as the temperature rises to within the tracking range.

Sensor 42 can develop output signals as a function of the temperature or any other monitorable condition associated with a work piece (not shown) within cavity 12 and provide the signals to controller 44. Dual temperature sensing and heating, as well as automated cooling rate and gas flow controls can also be used. Controller 44 in turn can be used to control operation of power supply 28, which can have one output connected to source 26 as described above and another output connected to valve 22 to control gas flow into cavity 12.

The invention may be practiced with microwave sources at, for example, both 915 MHz and 2.45 GHz provided by Communications and Power Industries (CPI), although radiation having any frequency less than about 333 GHz can be used. The 2.45 GHz system provided continuously variable microwave power from about 0.5 kilowatts to about 5.0 kilowatts. A 3-stub tuner allowed impedance matching for maximum power transfer and a dual directional coupler was used to measure forward and reflected powers. Also, optical pyrometers were used for remote sensing of the sample temperature.

As mentioned above, radiation having any frequency less than-about 333 GHz can be used consistent with this invention. For example, frequencies, such as power line frequencies (about 50 Hz to about 60 Hz), can be used, although the pressure of the gas from which the plasma is formed may be lowered to assist with plasma ignition. Also, any radio frequency or microwave frequency can be used consistent with this invention, including frequencies greater than about 100 kHz. In most cases, the gas pressure for such relatively high frequencies need not be lowered to ignite, modulate, or sustain a plasma, thereby enabling many plasma-assisted processes to occur at atmospheric pressures and above in any manufacturing environment.

The equipment was computer controlled using LabView 6i software, which provided real-time temperature monitoring and microwave power control. Noise was reduced by using sliding averages of suitable number of data points. Also, to improve speed and computational efficiency, the number of stored data points in the buffer array were limited by using shift-registers and buffer-sizing techniques. The pyrometer measured the temperature of a sensitive area of about 1 cm², which was used to calculate an average temperature. The pyrometer sensed radiant intensities at two wavelengths and fit those intensities using Planck's law to determine the temperature. It will be appreciated, however, that other devices and methods for monitoring and controlling temperature are also available and can be used consistent with this invention. For example, control software that can be used consistent with this invention is described in commonly owned, concurrently filed Kumar et al. PCT Application No. PCT/US03/14135 (Attorney Docket No. 1837.0033, now abandoned), which is hereby incorporated by reference in its entirety.

Chamber 14 had several glass-covered viewing ports with radiation shields and one quartz window for pyrometer access. Several ports for connection to a vacuum pump and a gas source were also provided, although not necessarily used.

System 10 also included a closed-loop deionized water cooling system (not shown) with an external heat exchanger cooled by tap water. During operation, the deionized water first cooled the magnetron, then the load-dump in the circulator (used to protect the magnetron), and finally the radiation chamber through water channels welded on the outer surface of the chamber.

In some embodiments of the invention, microwave absorbers 11 can be placed within chamber 14. Microwave absorber 11 can, for example, be formed of graphite plates or rods. Placement of microwave absorber 11 around chamber 14, and in some embodiments beneath cavity 12, can direct microwave power into the plasma. Such a technique maximizes the microwave power being directed to the plasma.

In some embodiments, multiple processes can be performed in chamber 14. For example, it typically takes a very long time to sinter and then braze powder metal parts. By controlling the process flow gas that enters cavity 12, it is possible to sinter, braze, and then apply a surface treatment to powder metal parts without moving the part from cavity 12. Any surface treatment can be accomplished, for example coating, carburization, nitriding, and other surface treatments.

Utilizing system 10 as shown in FIG. 1, a multi-process microwave plasma furnace with multiple cavities 12 can be formed. In such a furnace, a different process can be performed in each of the multiple cavities 12. For example, a part can be sintered in one of the multiple cavities 12 under proper conditions of temperature and environment and in another cavity 12 another part can be carburized or coated with another set of cavities.

### Plasma Catalysts

A plasma catalyst consistent with this invention can include one or more different materials and may be either passive or active. A plasma catalyst can be used, among other things, to ignite, modulate, and/or sustain a plasma at a gas pressure that is less than, equal to, or greater than atmospheric pressure.

One method of forming a plasma consistent with this invention can include subjecting a gas in a cavity to electromagnetic radiation having a frequency less than about 333 GHz in the presence of a passive plasma catalyst. A passive plasma catalyst consistent with this invention can include any object capable of inducing a plasma by deforming a local electric field (e.g., an electromagnetic field) consistent with this invention, without necessarily adding additional energy through the catalyst, such as by applying an electric voltage to create a spark.

A passive plasma catalyst consistent with this invention can also be a nano-particle or a nano-tube. As used herein, the term “nano-particle” can include any particle having a maximum physical dimension less than about 100 nm that is at least electrically semi-conductive. Also, both single-walled and multi-walled carbon nanotubes, doped and undoped, can be particularly effective for igniting plasmas consistent with this invention because of their exceptional electrical conductivity and elongated shape. The nanotubes can have any convenient length and can be a powder fixed to a substrate. If fixed, the nanotubes can be oriented randomly on the surface of the substrate or fixed to the substrate (e.g., at some predetermined orientation) while the plasma is ignited or sustained.

A passive plasma catalyst can also be a powder consistent with this invention, and need not comprise nano-particles or nano-tubes. It can be formed, for example, from fibers, dust particles, flakes, sheets, etc. When in powder form, the catalyst can be suspended, at least temporarily, in a gas. By suspending the powder in the gas, the powder can be quickly dispersed throughout the cavity and more easily consumed, if desired.

In one embodiment, the powder catalyst can be carried into the cavity and at least temporarily suspended with a carrier gas. The carrier gas can be the same or different from the gas that forms the plasma. Also, the powder can be added to the gas prior to being introduced to the cavity. For example, as shown in FIG. 1A, radiation source 52 can supply radiation to radiation cavity 55, in which plasma cavity 60 is placed. Powder source 65 can provide catalytic powder 70 into gas stream 75. In an alternative embodiment, powder 70 can be first added to cavity 60 in bulk (e.g., in a pile) and then distributed in the cavity in any number of ways, including flowing a gas through or over the bulk powder. In addition, the powder can be added to the gas for igniting, modulating, or sustaining a plasma by moving, conveying, drizzling, sprinkling, blowing, or otherwise, feeding the powder into or within the cavity.

In one experiment, a plasma was ignited in a cavity by placing a pile of carbon fiber powder in a copper pipe that extended into the cavity. Although sufficient radiation was directed into the cavity, the copper pipe shielded the powder from the radiation and no plasma ignition took place. However, once a carrier gas began flowing through the pipe, forcing the powder out of the pipe and into the cavity, and thereby subjecting the powder to the radiation, a plasma was nearly instantaneously ignited in the cavity.

A powder plasma catalyst consistent with this invention can be substantially non-combustible, thus it need not contain oxygen or burn in the presence of oxygen. Thus, as mentioned above, the catalyst can include a metal, carbon, a carbon-based alloy, a carbon-based composite, an electrically conductive polymer, a conductive silicone elastomer, a polymer nanocomposite, an organic-inorganic composite, and any combination thereof.

Also, powder catalysts can be substantially uniformly distributed in the plasma cavity (e.g., when suspended in a gas), and plasma ignition can be precisely controlled within the cavity. Uniform ignition can be important in certain applications, including those applications requiring brief plasma exposures, such as in the form of one or more bursts. Still, a certain amount of time can be required for a powder catalyst to distribute itself throughout a cavity, especially in complicated, multi-chamber cavities. Therefore, consistent with another aspect of this invention, a powder catalyst can be introduced into the cavity through a plurality of ignition ports to more rapidly obtain a more uniform catalyst distribution therein (see below).

In addition to powder, a passive plasma catalyst consistent with this invention can include, for example, one or more microscopic or macroscopic fibers, sheets, needles, threads, strands, filaments, yarns, twines, shavings, slivers, chips, woven fabrics, tape, whiskers, or any combination thereof. In these cases, the plasma catalyst can have at least one portion with one physical dimension substantially larger than another physical dimension. For example, the ratio between at least two orthogonal dimensions can be at least about 1:2, but could be greater than about 1:5, or even greater than about 1:10.

Thus, a passive plasma catalyst can include at least one portion of material that is relatively thin compared to its length. A bundle of catalysts (e.g., fibers) may also be used and can include, for example, a section of graphite tape. In one experiment, a section of tape having approximately thirty thousand strands of graphite fiber, each about 2-3 microns in diameter, was successfully used. The number of fibers in and the length of a bundle are not critical to igniting, modulating, or sustaining the plasma. For example, satisfactory results have been obtained using a section of graphite tape about one-quarter inch long. One type of carbon fiber that has been successfully used consistent with this invention is sold under the trademark Magnamite®, Model No. AS4C-GP3K, by the Hexcel Corporation, of Anderson, S.C. Also, silicon-carbide fibers have been successfully used.

A passive plasma catalyst consistent with another aspect of this invention can include one or more portions that are, for example, substantially spherical, annular, pyramidal, cubic, planar, cylindrical, rectangular or elongated.

The passive plasma catalysts discussed above can include at least one material that is at least electrically semi-conductive. In one embodiment, the material can be highly conductive. For example, a passive plasma catalyst consistent with this invention can include a metal, an inorganic material, carbon, a carbon-based alloy, a carbon-based composite, an electrically conductive polymer, a conductive silicone elastomer, a polymer nanocomposite, an organic-inorganic composite, or any combination thereof. Some of the possible inorganic materials that can be included in the plasma catalyst include carbon, silicon carbide, molybdenum, platinum, tantalum, tungsten, carbon nitride, and aluminum, although other electrically conductive inorganic materials may work just as well.

In addition to one or more electrically conductive materials, a passive plasma catalyst consistent with this invention can include one or more additives (which need not be electrically conductive). As used herein, the additive can include any material that a user wishes to add to the plasma. Therefore, the catalyst can include the additive itself, or it can include a precursor material that, upon decomposition, can form the additive. Thus, the plasma catalyst can include one or more additives and one or more electrically conductive materials in any desirable ratio, depending on the ultimate desired composition of the plasma and the process using the plasma.

The ratio of the electrically conductive components to the additives in a passive plasma catalyst can vary over time while being consumed. For example, during ignition, the plasma catalyst could desirably include a relatively large percentage of electrically conductive components to improve the ignition conditions. On the other hand, if used while sustaining the plasma, the catalyst could include a relatively large percentage of additives. It will be appreciated by those of ordinary skill in the art that the component ratio of the plasma catalyst used to ignite and sustain the plasma could be the same.

A predetermined ratio profile can be used to simplify many plasma processes. In many conventional plasma processes, the components within the plasma are added as necessary, but such addition normally requires programmable equipment to add the components according to a predetermined schedule. However, consistent with this invention, the ratio of components in the catalyst can be varied, and thus the ratio of components in the plasma itself can be automatically varied. That is, the ratio of components in the plasma at any particular time can depend on which of the catalyst portions is currently being consumed by the plasma. Thus, the catalyst component ratio can be different at different locations within the catalyst. And, the current ratio of components in a plasma can depend on the portions of the catalyst currently and/or previously consumed, especially when the flow rate of a gas passing through the plasma chamber is relatively slow.

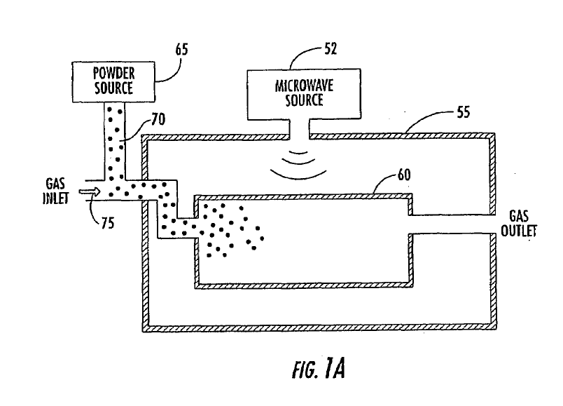

A passive plasma catalyst consistent with this invention can be homogeneous, inhomogeneous, or graded. Also, the plasma catalyst component ratio can vary continuously or discontinuously throughout the catalyst. For example, in FIG. 2, the ratio can vary smoothly forming a gradient along a length of catalyst 100. Catalyst 100 can include a strand of material that includes a relatively low concentration of a component at section 105 and a continuously increasing concentration toward section 110.

Alternatively, as shown in FIG. 3, the ratio can vary discontinuously in each portion of catalyst 120, which includes, for example, alternating sections 125 and 130 having different concentrations. It will be appreciated that catalyst 120 can have more than two section types. Thus, the catalytic component ratio being consumed by the plasma can vary in any predetermined fashion. In one embodiment, when the plasma is monitored and a particular additive is detected, further processing can be automatically commenced or terminated.

Another way to vary the ratio of components in a sustained plasma is by introducing multiple catalysts having different component ratios at different times or different rates. For example, multiple catalysts can be introduced at approximately the same location or at different locations within the cavity. When introduced at different locations, the plasma formed in the cavity can have a component concentration gradient determined by the locations of the various catalysts. Thus, an automated system can include a device by which a consumable plasma catalyst is mechanically inserted before and/or during plasma igniting, modulating, and/or sustaining.

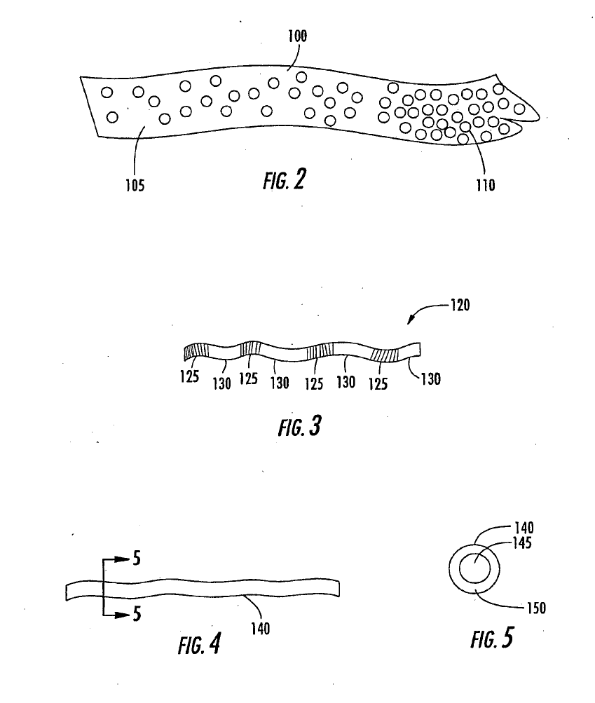

A passive plasma catalyst consistent with this invention can also be coated. In one embodiment, a catalyst can include a substantially non-electrically conductive coating deposited on the surface of a substantially electrically conductive material. Alternatively, the catalyst can include a substantially electrically conductive coating deposited on the surface of a substantially electrically non-conductive material. FIGS. 4 and 5, for example, show fiber 140, which includes underlayer 145 and coating 150. In one embodiment, a plasma catalyst including a carbon core is coated with nickel to prevent oxidation of the carbon.

A single plasma catalyst can also include multiple coatings. If the coatings are consumed during contact with the plasma, the coatings could be introduced into the plasma sequentially, from the outer coating to the innermost coating, thereby creating a time-release mechanism. Thus, a coated plasma catalyst can include any number of materials, as long as a portion of the catalyst is at least electrically semi-conductive.

Consistent with another embodiment of this invention, a plasma catalyst can be located entirely within a radiation cavity to substantially reduce or prevent radiation energy leakage. In this way, the plasma catalyst does not electrically or magnetically couple with the vessel containing the cavity or to any electrically conductive object outside the cavity. This prevents sparking at the ignition port and prevents radiation from leaking outside the cavity during the ignition and possibly later if the plasma is sustained. In one embodiment, the catalyst can be located at a tip of a substantially electrically non-conductive extender that extends through an ignition port.

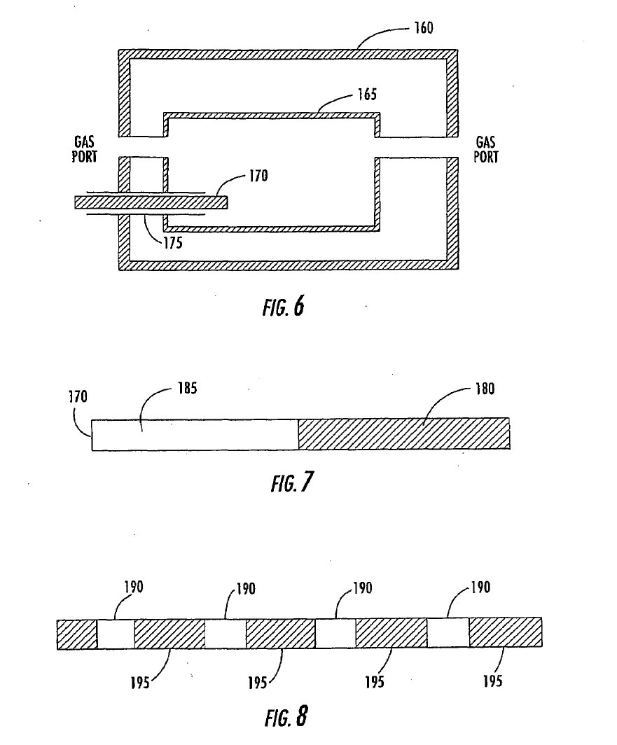

FIG. 6, for example, shows radiation chamber 160 in which plasma cavity 165 is placed. Plasma catalyst 170 is elongated and extends through ignition port 175. As shown in FIG. 7, and consistent with this invention, catalyst 170 can include electrically conductive distal portion 180 (which is placed in chamber 160) and electrically non-conductive portion 185 (which is placed substantially outside chamber 160, but can extend somewhat into chamber 160). This configuration can prevent an electrical connection (e.g., sparking) between distal portion 180 and chamber 160.

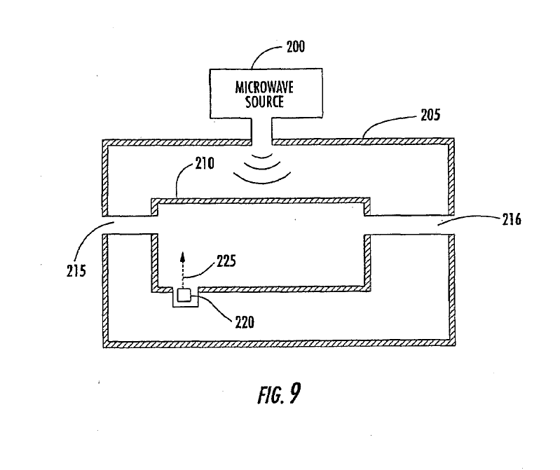

In another embodiment, shown in FIG. 8, the catalyst can be formed from a plurality of electrically conductive segments 190 separated by and mechanically connected to a plurality of electrically non-conductive segments 195. In this embodiment, the catalyst can extend through the ignition port between a point inside the cavity and another point outside the cavity, but the electrically discontinuous profile significantly prevents sparking and energy leakage.

Another method of forming a plasma consistent with this invention includes subjecting a gas in a cavity to electromagnetic radiation having a frequency less than about 333 GHz in the presence of an active plasma catalyst, which generates or includes at least one ionizing particle.

An active plasma catalyst consistent with this invention can be any particle or high energy wave packet capable of transferring a sufficient amount of energy to a gaseous atom or molecule to remove at least one electron from the gaseous atom or molecule in the presence of electromagnetic radiation. Depending on the source, the ionizing particles can be directed into the cavity in the form of a focused or collimated beam, or they may be sprayed, spewed, sputtered, or otherwise introduced.

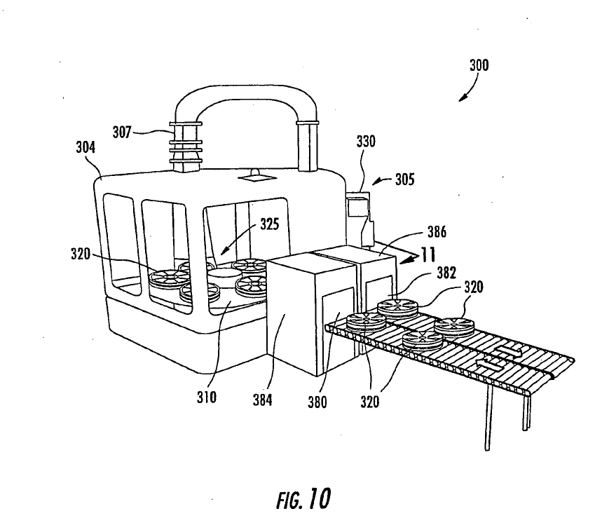

For example, FIG. 9 shows radiation source 200 directing radiation into radiation chamber 205. Plasma cavity 210 is positioned inside of chamber 205 and may permit a gas to flow therethrough via ports 215 and 216. Source 220 can direct ionizing particles 225 into cavity 210. Source 220 can be protected, for example, by a metallic screen which allows the ionizing particles to pass through but shields source 220 from radiation. If necessary, source 220 can be water-cooled.

Examples of ionizing particles consistent with this invention can include x-ray particles, gamma ray particles, alpha particles, beta particles, neutrons, protons, and any combination thereof. Thus, an ionizing particle catalyst can be charged (e.g., an ion from an ion source) or uncharged and can be the product of a radioactive fission process. In one embodiment, the vessel in which the plasma cavity is formed could be entirely or partially transmissive to the ionizing particle catalyst. Thus, when a radioactive fission source is located outside the cavity, the source can direct the fission products through the vessel to ignite the plasma. The radioactive fission source can be located inside the radiation chamber to substantially prevent the fission products (i.e., the ionizing particle catalyst) from creating a safety hazard.

In another embodiment, the ionizing particle can be a free electron, but it need not be emitted in a radioactive decay process. For example, the electron can be introduced into the cavity by energizing the electron source (such as a metal), such that the electrons have sufficient energy to escape from the source. The electron source can be located inside the cavity, adjacent the cavity, or even in the cavity wall. It will be appreciated by those of ordinary skill in the art that any combination of electron sources is possible. A common way to produce electrons is to heat a metal, and these electrons can be further accelerated by applying an electric field.

In addition to electrons, free energetic protons can also be used to catalyze a plasma. In one embodiment, a free proton can be generated by ionizing hydrogen and, optionally, accelerated with an electric field.

### Multi-Mode Radiation Cavities

A radiation waveguide, cavity, or chamber can be designed to support or facilitate propagation of at least one electromagnetic radiation mode. As used herein, the term “mode” refers to a particular pattern of any standing or propagating electromagnetic wave that satisfies Maxwell's equations and the applicable boundary conditions (e.g., of the cavity). In a waveguide or cavity, the mode can be any one of the various possible patterns of propagating or standing electromagnetic fields. Each mode is characterized by its frequency and polarization of the electric field and/or the magnetic field vectors. The electromagnetic field pattern of a mode depends on the frequency, refractive indices or dielectric constants, and waveguide or cavity geometry.

A transverse electric (TE) mode is one whose electric field vector is normal to the direction of propagation. Similarly, a transverse magnetic (TM) mode is one whose magnetic field vector is normal to the direction of propagation. A transverse electric and magnetic (TEM) mode is one whose electric and magnetic field vectors are both normal to the direction of propagation. A hollow metallic waveguide does not typically support a normal TEM mode of radiation propagation. Even though radiation appears to travel along the length of a waveguide, it may do so only by reflecting off the inner walls of the waveguide at some angle. Hence, depending upon the propagation mode, the radiation (e.g., microwave) may have either some electric field component or some magnetic field component along the axis of the waveguide (often referred to as the z-axis).

The actual field distribution inside a cavity or waveguide is a superposition of the modes therein. Each of the modes can be identified with one or more subscripts (e.g., TE₁₀ (“tee ee one zero”)). The subscripts normally specify how many “half waves” at the guide wavelength are contained in the x and y directions. It will be appreciated by those skilled in the art that the guide wavelength can be different from the free space wavelength because radiation propagates inside the waveguide by reflecting at some angle from the inner walls of the waveguide. In some cases, a third subscript can be added to define the number of half waves in the standing wave pattern along the z-axis.

For a given radiation frequency, the size of the waveguide can be selected to be small enough so that it can support a single propagation mode. In such a case, the system is called a single-mode system (i.e., a single-mode applicator). The TE₁₀ mode is usually dominant in a rectangular single-mode waveguide. As the size of the waveguide (or the cavity to which the waveguide is connected) increases, the waveguide or applicator can sometimes support additional higher order modes forming a multi-mode system. When many modes are capable of being supported simultaneously, the system is often referred to as highly moded.

A simple, single-mode system has a field distribution that includes at least one maximum and/or minimum. The magnitude of a maximum largely depends on the amount of radiation supplied to the system. Thus, the field distribution of a single mode system is strongly varying and substantially non-uniform.

Unlike a single-mode cavity, a multi-mode cavity can support several propagation modes simultaneously, which, when superimposed, result in a complex field distribution pattern. In such a pattern, the fields tend to spatially smear and, thus, the field distribution usually does not show the same types of strong minima and maxima field values within the cavity. In addition, as explained more fully below, a mode-mixer can be used to “stir” or “redistribute” modes (e.g., by mechanical movement of a radiation reflector). This redistribution desirably provides a more uniform time-averaged field distribution within the cavity.

A multi-mode cavity consistent with this invention can support at least two modes, and may support many more than two modes. Each mode has a maximum electric field vector. Although there may be two or more modes, one mode may be dominant and has a maximum electric field vector magnitude that is larger than the other modes. As used herein, a multi-mode cavity may be any cavity in which the ratio between the first and second mode magnitudes is less than about 1:10, or less than about 1:5, or even less than about 1:2. It will be appreciated by those of ordinary skill in the art that the smaller the ratio, the more distributed the electric field energy between the modes, and hence the more distributed the radiation energy is in the cavity.

The distribution of plasma within a plasma cavity may strongly depend on the distribution of the applied radiation. For example, in a pure single mode system, there may only be a single location at which the electric field is a maximum. Therefore, a strong plasma may only form at that single location. In many applications, such a strongly localized plasma could undesirably lead to non-uniform plasma treatment or heating (i.e., localized overheating and underheating).

Whether or not a single or multi-mode cavity is used consistent with this invention, it will be appreciated by those of ordinary skill in the art that the cavity in which the plasma is formed can be completely closed or partially open. For example, in certain applications, such as in plasma-assisted furnaces, the cavity could be entirely closed. See, for example, commonly owned, concurrently filed Kumar et al. PCT Application No. PCT/US03/14133 (Atty. Docket No. 1837.0020, now abandoned), which is fully incorporated herein by reference. In other applications, however, it may be desirable to flow a gas through the cavity, and therefore the cavity must be open to some degree. In this way, the flow, type, and pressure of the flowing gas can be varied over time. This may be desirable because certain gases, such as argon, which facilitate formation of plasma, can be easier to ignite but may not be needed during subsequent plasma processing.

### Mode-Mixing

For many plasma-assisted applications, a cavity containing a uniform plasma is desirable. However, because radiation can have a relatively long wavelength (e.g., several tens of centimeters), obtaining a uniform distribution can be difficult to achieve. As a result, consistent with one aspect of this invention, the radiation modes in a multi-mode cavity can be mixed, or redistributed, over a period of time. Because the field distribution within the cavity must satisfy all of the boundary conditions set by the inner surface of the cavity, those field distributions can be changed by changing the position of any portion of that inner surface.

In one embodiment consistent with this invention, a movable reflective surface can be located inside the radiation cavity. The shape and motion of the reflective surface should, when combined, change the inner surface of the cavity during motion. For example, an “L” shaped metallic object (i.e., “mode-mixer”) when rotated about any axis will change the location or the orientation of the reflective surfaces in the cavity and therefore change the radiation distribution therein. Any other asymmetrically shaped object can also be used (when rotated), but symmetrically shaped objects can also work, as long as the relative motion (e.g., rotation, translation, or a combination of both) causes some change in the location or orientation of the reflective surfaces. In one embodiment, a mode-mixer can be a cylinder that is rotable about an axis that is not the cylinder's longitudinal axis.

Each mode of a multi-mode cavity may have at least one maximum electric field vector, but each of these vectors could occur periodically across the inner dimension of the cavity. Normally, these maxima are fixed, assuming that the frequency of the radiation does not change. However, by moving a mode-mixer such that it interacts with the radiation, it is possible to move the positions of the maxima. For example, mode-mixer 38 can be used to optimize the field distribution within cavity 12 such that the plasma ignition conditions and/or the plasma sustaining conditions are optimized. Thus, once a plasma is excited, the position of the mode-mixer can be changed to move the position of the maxima for a uniform time-averaged plasma process (e.g., heating).

Thus, consistent with this invention, mode-mixing can be useful during plasma ignition. For example, when an electrically conductive fiber is used as a plasma catalyst, it is known that the fiber's orientation can strongly affect the minimum plasma-ignition conditions. It has been reported, for example, that when such a fiber is oriented at an angle that is greater than 60° to the electric field, the catalyst does little to improve, or relax, these conditions. By moving a reflective surface either in or near the cavity, however, the electric field distribution can be significantly changed.

Mode-mixing can also be achieved by launching the radiation into the applicator chamber through, for example, a rotating waveguide joint that can be mounted inside the applicator chamber. The rotary joint can be mechanically moved (e.g., rotated) to effectively launch the radiation in different directions in the radiation chamber. As a result a changing field pattern can be generated inside the applicator chamber.

Mode-mixing can also be achieved by launching radiation in the radiation chamber through a flexible waveguide. In one embodiment, the waveguide can be mounted inside the chamber. In another embodiment, the waveguide can extend into the chamber. The position of the end portion of the flexible waveguide can be continually or periodically moved (e.g., bent) in any suitable manner to launch the radiation (e.g., microwave radiation) into the chamber at different directions and/or locations. This movement can also result in mode-mixing and facilitate more uniform plasma processing (e.g., heating) on a time-averaged basis. Alternatively, this movement can be used to optimize the location of a plasma for ignition or other plasma-assisted process.

If the flexible waveguide is rectangular, a simple twisting of the open end of the waveguide will rotate the orientation of the electric and the magnetic field vectors in the radiation inside the applicator chamber. Then, a periodic twisting of the waveguide can result in mode-mixing as well as rotating the electric field, which can be used to assist ignition, modulation, or sustaining of a plasma.

Thus, even if the initial orientation of the catalyst is perpendicular to the electric field, the redirection of the electric field vectors can change the ineffective orientation to a more effective one. Those skilled in the art will appreciate that mode-mixing can be continuous, periodic, or preprogrammed.

In addition to plasma ignition, mode-mixing can be useful during subsequent plasma processing to reduce or create (e.g., tune) “hot spots” in the chamber. When a radiation cavity only supports a small number of modes (e.g., less than 5), one or more localized electric field maxima can lead to “hot spots” (e.g., within cavity 12). In one embodiment, these hot spots could be configured to coincide with one or more separate, but simultaneous, plasma ignitions or processing events. Thus, the plasma catalyst can be located at one or more of those ignition or subsequent processing positions.

### Multi-Location Ignition

A plasma can be ignited using multiple plasma catalysts at different locations. In one embodiment, multiple fibers can be used to ignite the plasma at different points within the cavity. Such multi-point ignition can be especially beneficial when a uniform plasma ignition is desired. For example, when a plasma is modulated at a high frequency (i.e., tens of Hertz and higher), or ignited in a relatively large volume, or both, substantially uniform instantaneous striking and restriking of the plasma can be improved. Alternatively, when plasma catalysts are used at multiple points, they can be used to sequentially ignite a plasma at different locations within a plasma chamber by selectively introducing the catalyst at those different locations. In this way, a plasma ignition gradient can be controllably formed within the cavity, if desired.

Also, in a multi-mode cavity, random distribution of the catalyst throughout multiple locations in the cavity increases the likelihood that at least one of the fibers, or any other passive plasma catalyst consistent with this invention, is optimally oriented with the electric field lines. Still, even where the catalyst is not optimally oriented (not substantially aligned with the electric field lines), the ignition conditions are improved.

Furthermore, because a catalytic powder can be suspended in a gas, each powder particle may have the effect of being placed at a different physical location within the cavity, thereby improving ignition uniformity within the cavity.

### Dual-Cavity Plasma Igniting/Sustaining

A dual-cavity arrangement can be used to ignite and sustain a plasma consistent with this invention. In one embodiment, a system includes at least a first ignition cavity and a second cavity in fluid communication with the first cavity. To ignite a plasma, a gas in the first ignition cavity can be subjected to electromagnetic radiation having a frequency less than about 333 GHz, optionally in the presence of a plasma catalyst. In this way, the proximity of the first and second cavities may permit a plasma formed in the first cavity to ignite a plasma in the second cavity, which may be sustained with additional electromagnetic radiation.

In one embodiment of this invention, the first cavity can be very small and designed primarily, or solely for plasma ignition. In this way, very little radiation energy may be required to ignite the plasma, permitting easier ignition, especially when a plasma catalyst is used consistent with this invention.

In one embodiment, the first cavity may be a substantially single mode cavity and the second cavity is a multi-mode cavity. When the first ignition cavity only supports a single mode, the electric field distribution may strongly vary within the cavity, forming one or more precisely located electric field maxima. Such maxima are normally the first locations at which plasmas ignite, making them ideal points for placing plasma catalysts. It will be appreciated, however, that when a plasma catalyst is used, it need not be placed in the electric field maximum and, many cases, need not be oriented in any particular direction.

### Illustrative Plasma-Assisted Processing in a Manufacturing Line

Methods and apparatus for plasma-assisted processing of work pieces in a manufacturing line may be provided. A plasma-assisted process can include any operation, or combination of operations, involving the use of a plasma. The work pieces can be plasma-processed continuously, periodically, in batches, in sequence, or any combination thereof.

Plasma-assisted processes consistent with this invention can include, for example, sintering, annealing, normalizing, spheroiding, tempering, age hardening, case hardening, or any other type of hardening or process that involves heat-treatment. Plasma-assisted processing can also include joining materials that are the same or different from one another. For example, plasma-assisted processing can include brazing, welding, bonding, soldering, and other types of joining processes. Additional plasma-assisted processes, such as doping, nitriding, carburizing, decrystallizing, carbo-nitriding, cleaning, sterilizing, vaporizing, coating, and ashing, can also be included consistent with this invention.

FIGS. 10-13 show various views of illustrative apparatus 300 for plasma-assisted sintering. It will be appreciated, however, that apparatus 300 can be used to perform any other plasma-assisted process consistent with this invention as well.

FIG. 10 shows a perspective view of illustrative apparatus 300 for plasma-assisted processing of one or more work pieces consistent with this invention. Apparatus 300 can include, for example, radiation source 305, radiation waveguide 307 through which radiation passes from source 305 toward irradiation zone 325, and conveyor 310 for sequentially moving work pieces 320 into and out of irradiation zone 325 adjacent waveguide 307. Apparatus 300 can also include one or more gas ports (not shown) for conveying a gas in, out, or through zone 325 to enable plasma formation there.

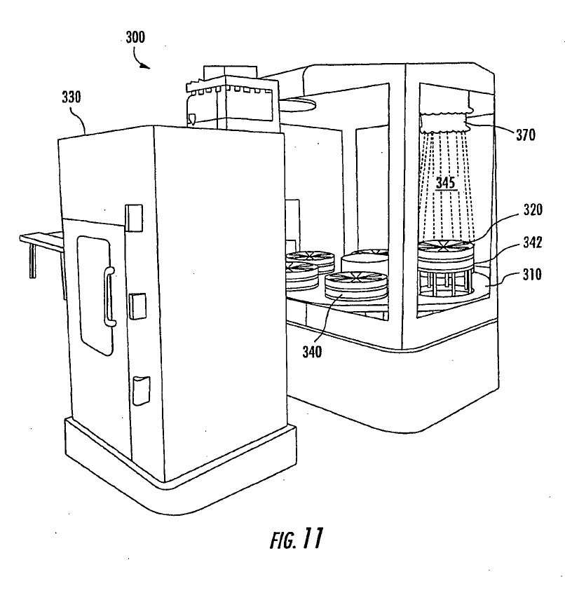

FIG. 11 shows another perspective view of apparatus 300, taken along line 11-11 of FIG. 10. Any of radiation source 305 and power supply 335 (not shown) for powering source 305 can be located in housing 330. It will be appreciated, however, that source 305 and supply 335 can be located anywhere in relation to the floor plan, or to meet any other physical or dimensional requirement, of plasma-assisted processing apparatus 300. This includes separating source 305 from supply 335, in or out of housing 330.

Source 305 can irradiate zone 325 from any direction. For example, radiation source 305 can be located above, below, or in the same horizontal plane as zone 325 and waveguide 307 can be used to direct the radiation from source 305 to zone 325. If radiation source 305 is capable of directing radiation in the form of a beam (e.g., a diverging, converging, or collimated beam), then waveguide 307 can be eliminated and the zone can be irradiated simply by directing the radiation beam toward zone 325. In another embodiment, source 305 can supply radiation to zone 325 via one or more coaxial cable (not shown). In yet another embodiment, the radiation output of source 305 can directly irradiate zone 325.

When apparatus 300 includes waveguide 307, waveguide can have any cross-sectional shape to selectively propagate any particular radiation mode or modes. For example, as shown in FIG. 10, waveguide 307 can have a rectangular cross-section, but could also have a round, oval, or other shape capable of propagating radiation. Also, waveguide 307 can be linear, arched, spiral, serpentine, or any other convenient form. In general, waveguide 307 can be used to couple radiation source 305 to a radiation zone (e.g., a cavity) for forming a plasma and performing any type of plasma-assisted process.

A conveyor can include at least one carrier portion for conveying work pieces. As used herein, a carrier portion can be any portion of a conveyor adapted to carry, support, hold, or otherwise mount one or more work pieces. As shown in FIG. 11, for example, carrier portions 340 and 342 can be circular plates on which one or more work pieces can be placed and conveyed. FIG. 12, for example, shows a top plan view of conveyor 310, including six holes 350 on which carrier portions 340 and 342 can be positioned. Although conveyor 310 has been configured to hold up to six carrier portions, conveyor 310 can be configured to hold more or less carrier portions, if desired. It will be appreciated that a carrier portion consistent with this invention can also be integral with the conveyor or with the work piece.

Conveyor 310 need not include holes 350 consistent with this invention. For example, as shown in FIG. 14, upper surface 360 of conveyor 362 can include one or more recesses 364 in which one or more work pieces 366 can be placed while conveyor 362 rotates or otherwise moves. Alternatively, a conveyor consistent with this invention can have raised portions or even no surface features at all (not shown). That is, the supporting surface of the conveyor can be substantially flat and one or more work pieces can be placed in any convenient orientation on the surface. In this way, differently shaped work pieces can be used with the same conveyor consistent with this invention.

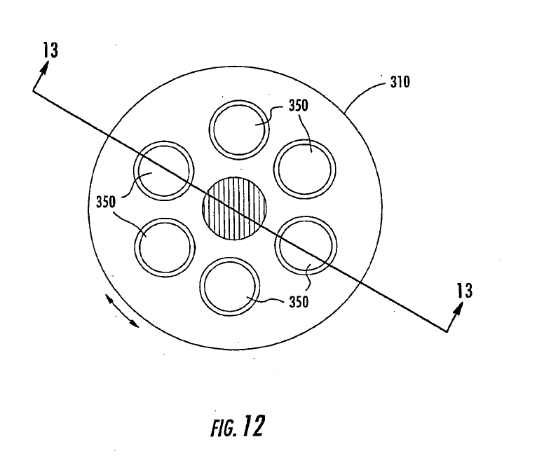

Any number of work pieces can be carried by carrier portions consistent with this invention. FIGS. 11 and 13, for example, show that carrier portions 340 and 342 each carry a single work piece. In this case, the work piece can be a powdered metal part to be sintered using a plasma. Also, as shown in FIG. 13, carrier portions 340 and 342 can be configured or shaped to fit in or otherwise attach to conveyor 310. For example, the sides of carrier portions 340 and 342 can be tapered so that they precisely fit into holes 350. In addition, the upper surface of the carrier portions can be customized or otherwise adapted so that one or more work pieces are carried or supported in a predetermined position. For this purpose, one or more adaptors can be used with the same carrier portion so that it can be used for differently shaped work pieces and plasma-assisted processes.

A waveguide and at least one carrier portion can cooperate to form a plasma-processing cavity consistent with this invention. For example, FIG. 11 shows tip portion 370 of waveguide 307 facing downward at work piece 320, which is located on carrier portion 342. Thus, work piece 320 can be located between tip portion 370 and carrier portion 342 that, together, form cavity 369 (shown in FIG. 13) in which a plasma can be formed. It will be appreciated that cavity 369 can be open or closed and the “openness” of the cavity depends on the relative position of tip portion 370 with respect to carrier portion 342.

As shown in FIGS. 11 and 13, for example, work piece 320 can be lifted by carrier portion 342 toward tip portion 370 by actuator 372, making the size and openness of cavity 369 smaller. In one embodiment, the gap between tip portion 370 and carrier portion 342 is reduced such that cavity 369 is essentially closed before a plasma is ignited, essentially trapping gas and forming a plasma with that gas. In another embodiment consistent with this invention, a gap remains before, during, or after plasma processing, permitting a gas to flow through the cavity.

In any case, cavity 369 can have the appropriate dimensions to substantially confine the plasma and prevent plasma formation outside cavity 369. Thus, work pieces 320, which can be carried by carrier portions 340 and 342, can be conveyed sequentially into a plasma processing station below tip 370 by rotating conveyor 310 with motor 374.

To prevent gas and plasma from traveling up through waveguide 370, radiation-transmissive plate 373 (e.g., made from quartz or ceramic), can be used as shown in FIG. 13. In this case, plate 373 can act as an upper surface of plasma cavity 369. Waveguide tip 370 can include lip 371, which may be cylindrical, conical, or any other shape configured to form a suitable plasma cavity. During operation, lips 371 can be positioned around part 320 to form the sides of cavity 369. Finally, carrier portion 342, part 320, or conveyor 310 can be used to form the lower part of cavity 369. FIG. 11 illustrates how radiation 345 can be directed toward part 320 into cavity 369 from waveguide tip 370. In practice, however, the distance between tip 370 and part 320 could be reduced to perform a plasma process, thereby making cavity 369 less open.

In another embodiment (not shown), a work piece can be lowered or otherwise positioned at a plasma-processing station using the carrier portion. And, once again, a processing cavity can be formed between either the work piece or the carrier portion and a waveguide tip. Alternatively, as shown in FIG. 1, a plasma-processing cavity can be formed in a substantially radiation-transmissive vessel. In this case, neither the carrier portion nor the waveguide necessarily forms a portion of the plasma cavity. In another embodiment, the waveguide housing can be replaced with a radiation-transmissive housing and used to form a plasma cavity similar to the cavity shown in FIG. 1A, for example. In other words, the waveguide need not be coupled directly to the plasma-processing cavity. It can be coupled to a larger radiation cavity in which the plasma cavity is positioned.

Although work pieces can be carried into place by carrier portions, those work pieces need not carry or otherwise support the work pieces during processing. That is, carrier portions can place the work pieces in a plasma cavity and then remove them from the cavity after processing. The same or different carrier portions can also be used to remove the work pieces after they have been plasma-processed.

As used herein, a conveyor can be any device capable of moving work pieces from one location to another, and in particular to and from a plasma-processing station. Thus, in addition, or as an alternative, to the rotatable table-type conveyors shown in FIGS. 10-14, a conveyor consistent with this invention can include, for example, a belt, a track, a robot, a turntable, a roller, a wheel, a chain, a bucket, a tray, a guide rail, a lift, a screw, a push bar, a ribbon screw, a rail system, an under floor system, a roller system, a slider system, a slat system, a gravity feed system, a chain on edge system, a cable system, a magnetic conveyor, a pulley system, a reciprocating conveyor, or any other moving and positioning mechanisms.

Conveyor 310, as well as plasma-processing cavity 325, can be located in radiation chamber 304 to prevent potentially harmful radiation from escaping the processing station. Radiation chamber 304 can be substantially reflective or otherwise opaque to the radiation supplied by source 305 and being used to form the plasma. Chamber 304 can be particularly useful when one or more of the components that form cavity 325 are substantially transmissive to the radiation supplied by source 305 or when cavity 325 is at least partially open. It will be appreciated, however, that if cavity 325 is sealed (e.g., by waveguide tip 370 and carrier portion 320) potentially harmful radiation can not escape cavity 325 during plasma-assisted processing and chamber 304 may be redundant. However, chamber 304 may still be used to trap the processing gas.

Apparatus 300 can include one or more ports for moving work pieces in and out of apparatus 300. For example, apparatus 300 can include entrance port 380 for moving parts 320 into apparatus 300 for plasma-assisted processing. Entrance port 380 can be part of gas lock 384 that substantially isolates a processing gas (e.g., argon, helium, nitrogen, etc.) in chamber 304 from a gas (e.g., air) outside chamber 304. Similarly, apparatus 300 can include exit port 382 for removing parts 320 from apparatus 300 after plasma-assisted processing is complete. Exit port 382 can also be part of gas lock 386 that substantially isolates the processing gas from the gas outside chamber 304. Mechanical arms or guides (not shown) can be used to assist in the loading of parts onto, and the unloading of parts off of, conveyor 310, if desired.

As described more fully above, an active or passive plasma catalyst can be used to ignite, modulate, or sustain a plasma at pressures below, at, or above atmospheric pressure consistent with this invention. Because these catalysts have already been described in detail above, they will not be described again here. In addition, sparking devices, and other devices for inducing a plasma, can also be used consistent with this invention. In any case, the plasma catalyst can be placed in an operable location to relax, or improve, the plasma-ignition requirements. In one embodiment, the plasma catalyst can be located on and carried by a carrier portion or the work piece itself. In another embodiment, the plasma catalyst can be attached or otherwise positioned adjacent to waveguide tip 370.

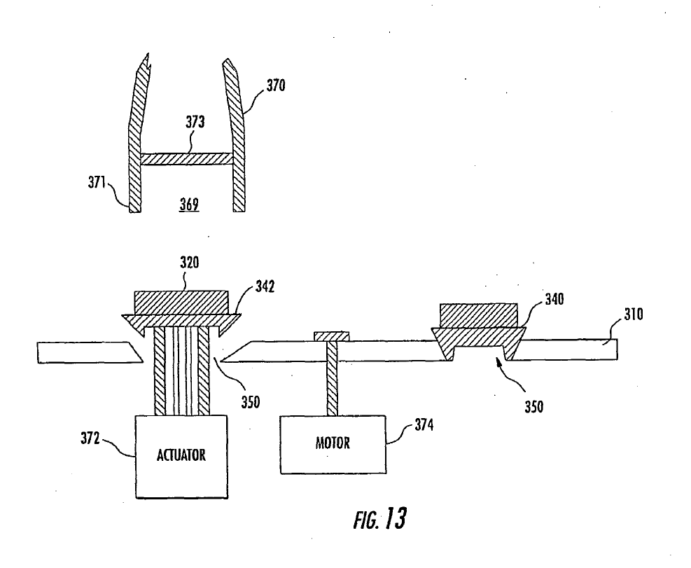

FIG. 15 shows a flow-chart for illustrative method 400 of plasma-processing a plurality of work pieces consistent with this invention. The method can include: placing each of the plurality of work pieces in a plurality of movable carriers in step 405, sequentially moving each of the movable carriers on a conveyor into an irradiation zone in step 410, flowing a gas into the zone in step 415, igniting the gas in the zone by subjecting the gas to radiation to form a plasma in step 420, sustaining the plasma for a period of time sufficient to plasma-process at least one of the work pieces in the zone in step 425, and advancing the conveyor to move the at least one processed work piece out of the zone in step 430.

A plasma-processing method consistent with this invention can selectively expose one or more of the work pieces to a plasma. This includes exposing one or more work pieces for a relatively long period of time compared to the others, or to a higher temperature plasma for the same period of time, or a combination thereof. For example, as shown in FIG. 10, work pieces located in radiation zone 325 will be exposed to a plasma while the other work pieces within chamber 304, but not in zone 325, will not be so exposed. Moreover, the rate of rotation of conveyor 310 can be varied or the length of time that a work piece remains in zone 325 can be varied. Moreover, as shown in FIG. 11, the height of carrier 342 and tip 370 can be varied to change the radiation intensity in zone 325 and therefore the plasma intensity there.

In one embodiment, an electric bias can be applied to one or more of the work pieces within an irradiation zone to produce a more uniform and rapid plasma-assisted process. For example, a potential difference can be applied between an electrode (e.g., suspended in a plasma cavity) and a work piece. The work piece can be connected to a voltage source directly, or through one of the moveable carriers. The voltage source can be outside the applicator or irradiation zone and the voltage can be applied through a microwave filter to prevent, for example, microwave energy leakage. The applied voltage can, for example, take the form of a continuous or pulsed DC or AC bias. In the case of a plasma-assisted coating process, the applied voltage may attract charged ions, energizing them, and facilitate coating adhesion and quality.

### Multi-Chamber Processing

As described above, FIG. 1 illustrates basic elements of a reactor utilized to process parts utilizing microwave generated plasmas at atmospheric pressure. Once the plasma is formed in cavity 12, the microwaves coupled to the plasma result in the transfer of energy and other constituents included in the plasma to a subject material inserted into cavity 12. In general, cavity 12 is larger than the subject material, or work piece 320, that is to be treated, often on the order of ¼ wavelength of the microwave frequency being used. The smaller the size of cavity 12, the better energy efficiency is realized in treating work piece 320 with the resulting plasma.

Two frequencies in the microwave range are currently available for industrial use, 2.45 GHz and 915 MHz. As discussed above, reactors such as that shown in FIG. 1 can be operated at any frequency less than about 333 GHz. Many devices are available for generation of microwave energy, however, in many industrial applications microwave source 26 can be a magnetron. In one experimental reactor, chamber 14 was a thick-walled metallic chamber that housed cavity 12. During operation, chamber 14 is sealed atmospherically to prevent leakage of microwaves. Microwave source 26 is mounted below chamber 14 and microwave radiation is directed into chamber 14 via waveguide 30. As shown in FIG. 1, the process is controlled by controller 44, which can be a computer operating controller software. The remaining system includes gas handling devices, power supplies, and various sensors that monitor the process being performed in cavity 12. Observation ports may also be included. In any scale-up of an experimental reactor to an industrial process, the elements described above with respect to FIG. 1 are included.

Further, the number of industrial processes that can benefit by utilization of reactors according to the present invention is large and can, for example, include sintering, brazing, melting, bonding, heat treatments, carburizing, coatings, corrosion treatments, exhaust and waste treatment, and gas production. Each of these processes may require different considerations in the reactor utilized to perform that process. However, in some cases, several of these processes may be combined in one manufacturing line. Therefore, some embodiments of the invention provide for a manufacturing line with multiple reactors that can perform multiple processes on a work piece.

A microwave processing system according to some embodiments of the present invention can provide a batch, semi-continuous or continuous processing of any processing procedure. FIG. 16 shows a plan view of a multi-chamber system 1600 according to some embodiments of the present invention. As shown in FIG. 16, multiple reactors 1602 are utilized. In the embodiment of multi-chamber system 1600 shown in FIG. 16, three reactors 1602 are illustrated. In general, multi-chamber system 1600 can have any number of reactors 1602. Each of reactors 1602 can be an independent plasma reactor containing multiple magnetrons 1605, which in turn can be independently controlled. Radiation chamber staging area 1604 can be utilized to prepare work pieces for processing in one of reactors 1602 or can perform a preheating of the work pieces prior to entering the plasma reactor for processing. Work pieces are shuttled between areas on a conveyor system 1601. In some embodiments, work pieces are conveyed throughout multi-chamber system 1600 with bi-directional powered rollers or something similar that provides accurate positioning of each of the work pieces. Sensors (not shown) are located throughout the system to insure accurate positioning of work pieces. Bar code sensors can also be located throughout multi-chamber system 1601 to track and control the progress of work pieces. For example, sensors located in radiation chamber staging 1604 can include bar code readers that can indicate to system 1600 the correct reactor 1602 to which to direct the work piece as well as what process is to be performed in that reactor 1602. Additionally, bar codes can be utilized to direct the work pieces to other areas of the system.

Conveyance system 1601 can transport work pieces between reactors 1602 and radiation chamber staging 1604. In some embodiments, system 1600 also includes buffer cooling pots 1606. In many manufacturing processes, especially of metal parts, the cool down cycle is more critical than the heat up cycle. System 1600 can employ multiple cool down Buffer Pods 1606 that provide an environment outside of reactors 1602 for quenching or slow cooling of a work piece depending upon the process being performed on that work piece in system 1602. Each buffer pod 1606 can be independently controlled for each work piece that is processed in them. Buffer pods 1606 can each include independent cooling and heating systems as well as gas flow systems to control the temperature and environment of work pieces.

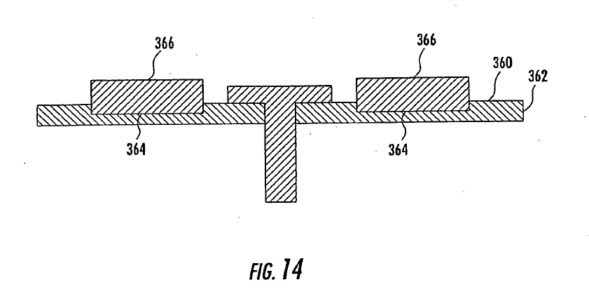

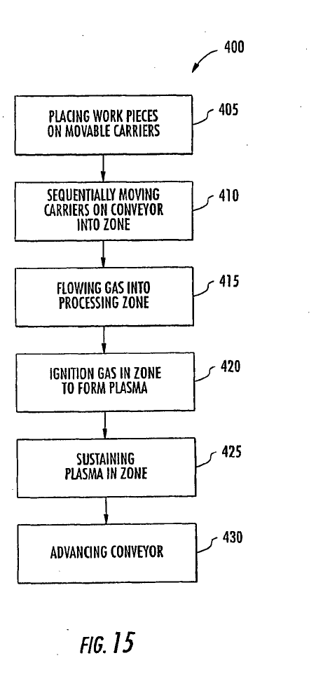

FIGS. 17A through 17C illustrate system 1600 in further detail. As shown in FIGS. 17A through 17C, reactors 1602 are typically enclosed in housing 1610. Housing 1610 can include doors 1612 that can be sealed to prevent leakage of radiation and to further control the environment in which the work pieces are transported. As shown in FIG. 17B, parts can be transported in conveyance system 1601 by rollers or conveyor belts. Although the arrangement of buffer pods 1606, reactors 1602, and staging area 1604 is arranged to be grouped in FIGS. 16 and 17A through 17C, one skilled in the art will recognize that other relative arrangements of components may be more convenient for a particular manufacturing process.

Modularity and flexibility are some of the more salient aspects of embodiments of this invention. For example, a system can contain one plasma reactor 1602 or can be expanded to “N” reactors 1602, depending upon the production throughput that is required. Further, each reactor 1602 can have one magnetron or several. In some embodiments, reactor 1602 is octagonally shaped and includes eight magnetrons. The power level of each magnetron can be the same or different depending upon the process power requirements. That is, each magnetron can have a different maximum power output, or they can all be the same. Some magnetrons can be left unused and brought into service in the event that one of the active magnetrons becomes faulty. This minimizes any potential downtime on the flow rate through the system.

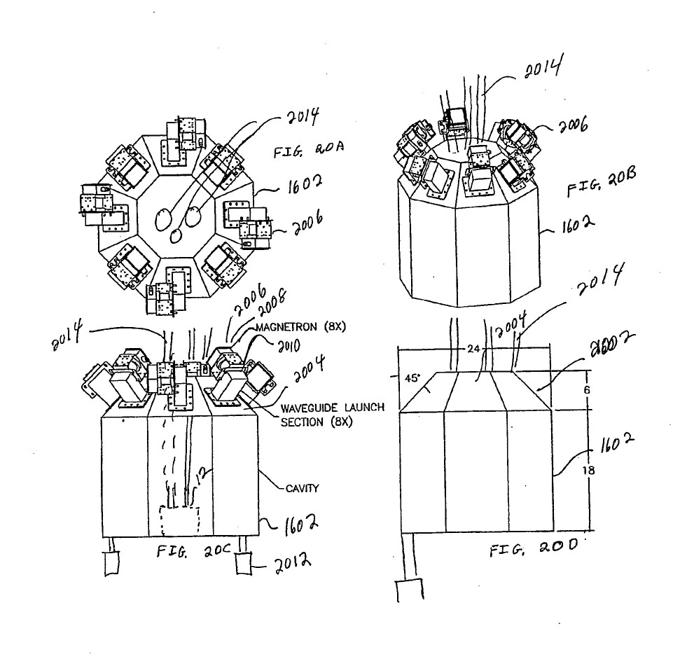

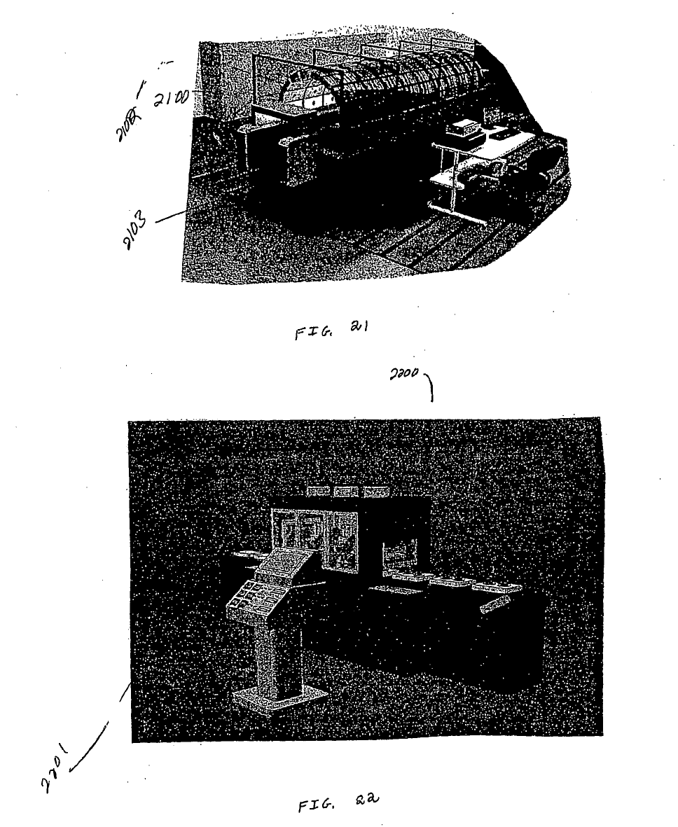

FIGS. 20A through 20D illustrate an embodiment of reactor 1602. As shown in FIG. 20D, reactor 1602 can be octogonally shaped with a tapered top 2002. As shown in FIG. 20C, a magnetron assembly 2006 can be mounted on each section 2004 of tapered top 2002. Magnetron assembly 2006 can include a magnetron 2008 coupled to a waveguide 2010. Microwave power generated in magnetron 2008 is coupled into reactor 1602 through waveguide 2004. In some embodiments, reactor 1602 can be a cavity such as that shown as cavity 12 in FIG. 1. In some embodiments, a separate cavity area can be provided in each of reactor 1602. FIG. 20A shows a top planar view of reactor 1602. FIGS. 20B through 20D show alternate views of reactor 1602.

As shown in FIGS. 20A through 20D, magnetron assemblies 2006 can be mounted on the octagonal roof shape whereby each magnetron assembly 2006 is pointed toward the target plasma cavity contained within each reactor 1602. In this manner, the initial radiation coming from the magnetrons strikes the target area. It should be noted that the shapes described for the reactors can take on different form factors as required such as hexagonal or even round. Any resulting shape will have to be optimized for energy distribution within reactor 1602.

As is further shown in FIGS. 20C and 20D, pistons 2012 can be included to vertically position reactors 1602 in system 1600. In the up position, work parts can be positioned properly in reactor 1602 prior processing. Once in position, reactor 1602 is lowered by a control system and seals reactor to the base foundation. The seals are appropriate for insuring minimal radiation leakage. Once the part heating cycle is completed, the reactor rises again and allows the processed part to be directed out of the system or to an appropriate buffer cooling pod 1606 according to the process being implemented. Once the cooling cycle is completed, the part exits from the system as previously described. In some embodiments, pistons can be provided to lift the work piece into the cavity instead of lifting chamber 1600.

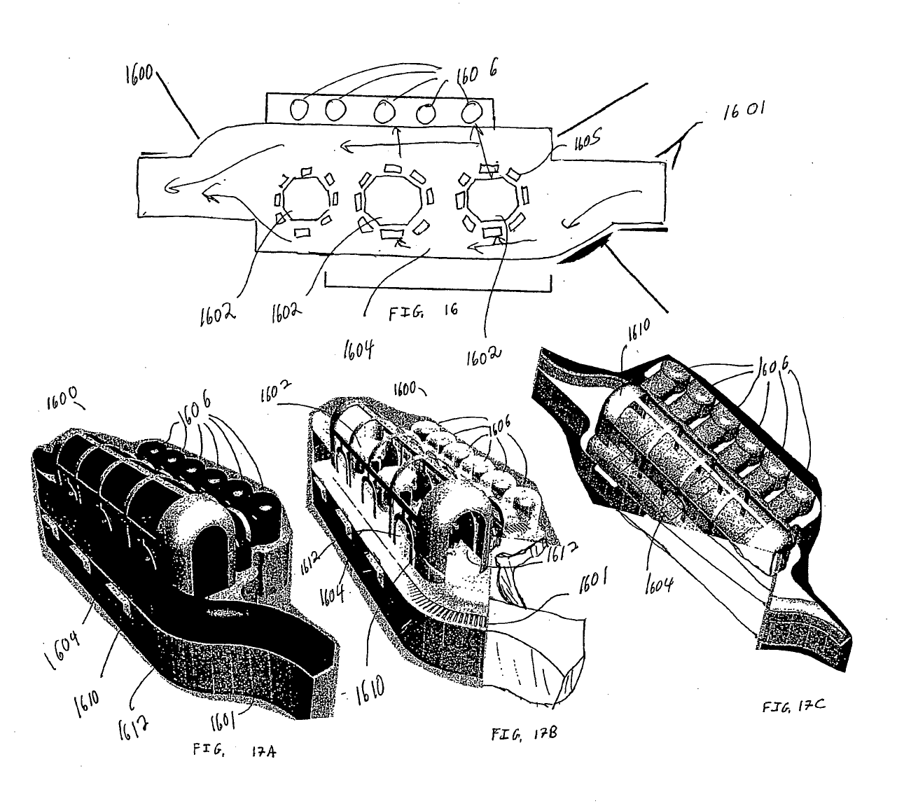

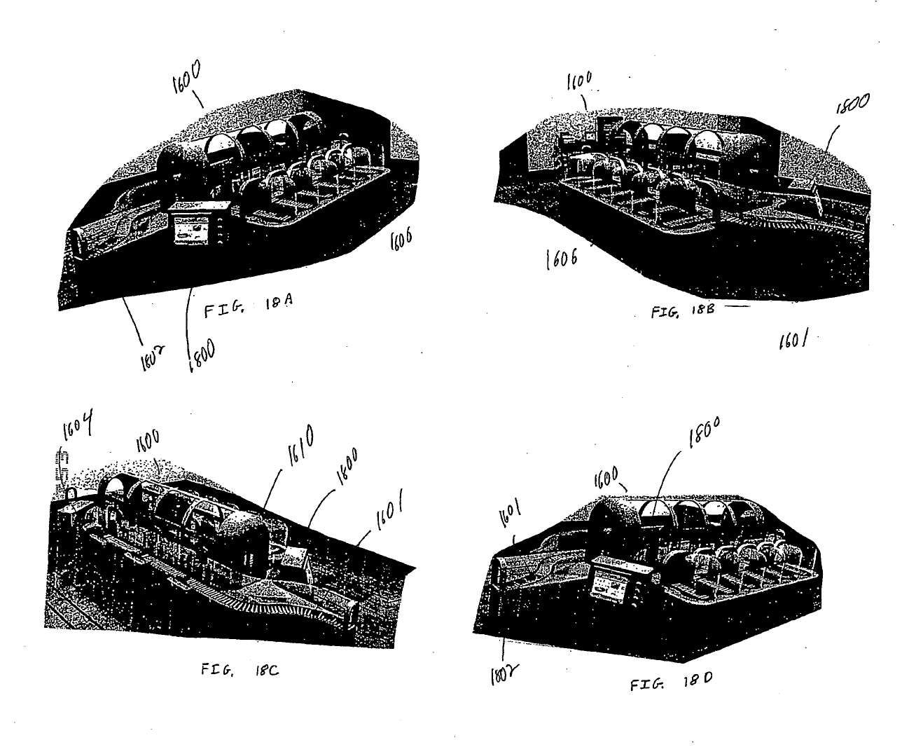

FIGS. 18A through 18D further illustrate embodiments of system 1600. As shown in FIG. 18A, system 1600 is controlled by controller 1800. Conveyance system 1601 perform at least two functions The first function is to provide a base for work pieces 1802 to be conveyed through system 1600 in a fashion controlled by controller 1800. The second function is to form the bottom of the plasma cavity within reactor 1602. Within reactor 1602, conveyance system 1601 can be formed from a class of ceramic appropriate for forming the bottom of a cavity such as cavity 12 in FIG. 1. The top half or mating half of a plasma cavity such as shown as cavity 12 in FIG. 20C can be permanently fixed in reactor 1600. The top half of the cavity is made from the same or similar material as the carriers of carrier system 1602. This upper cavity half is positioned over the work part and carrier when the reactor is lowered into position, as shown in FIG. 20C.

As illustrated in FIGS. 20A through 20D, gas, exhaust, and electrical accesses 2014 to the interior of reactor 1602 can be positioned at the top of reactor 1602. Accesses 2014 having gas and exhaust lines can then be coupled to the top half of the subject cavity 12 contained in reactor 1602, as is illustrated in FIG. 20C. This provides a variety of gases required for the process to take place and proper exhaust of byproducts of the results taking place within. The required gases flow rates and exhausts requirements can be controlled by controller 1800.

In some embodiments, as a precursor for processing a work piece, an ignition catalyst can be placed next to the part(s) on the carrier before entering the system. In some embodiments, the ignition catalyst can be transported into the gas flow accesses 2014 of reactor 1602. From the part staging area, into the reactor, to the cooling pods, doors 1612 are located that open and close under system control to insure that no undesirable gases enter or exit system 1600 during operation. Additionally, doors 1612 provide a secondary guard against radiation leakage outside the system.

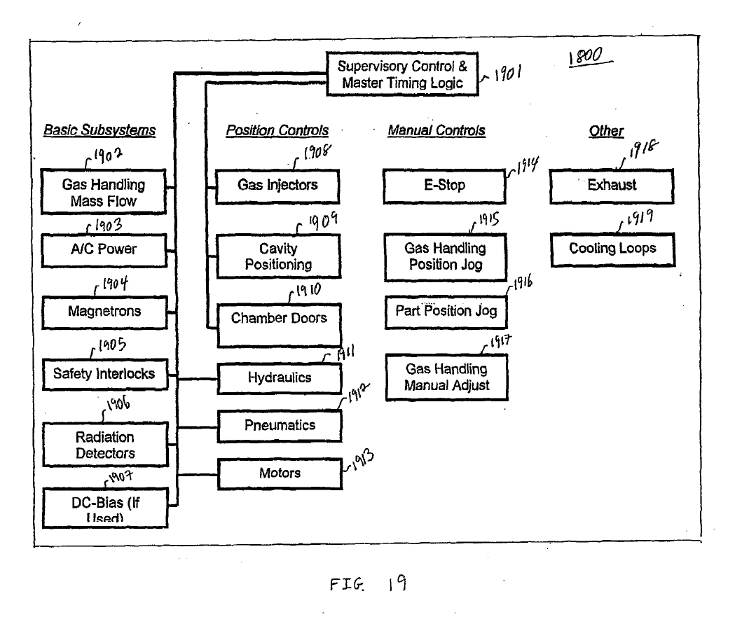

FIG. 19 illustrates an embodiment of control system 1800. Control system 1800 controls the operation of system 1600. As shown in FIG. 19, a control and master timing logic 1901 controls many of the sub systems system 1600, including gas flow 1902, gas injectors 1908, power 1903, magnetrons 1904, safety interlocks 1905, radiation detectors 1906, bias 1907, cavity positioning 1909, chamber doors 1910, hydraulics 1911, pneumatics 1912, and motors 1913. Gas handling 1902 and gas injectors 1908 control the amount of gas and the mix of gas flowing into each of reactors 1602. Magnetrons 1904 controls which of magnetron assemblies 2006 on each of reactors 1602 is activated. DC-bias 1907 controls whether power is applied to the work piece during processing in each of reactors 1602. Safety interlocks 1905 and radiation detectors 1906 together determine whether system 1600 is safe to operate. Chamber doors 1910 opens and closes doors 1612 as needed. Hydraulics 1911, pneumatics 1912, and motors 1913 control position of reactors, doors, and parts throughout system 1600. Some controls may be manual, such as an emergency stop 1914, gas handling adjustments 1915, part position adjustments 1916, and gas handling manual adjustments 1917. Cooling loops 1919 and exhaust loops 1918 may also be independent.

In some embodiments, the control of the system is a two-level scheme. At the top of the hierarchy would be a supervisory control 1901, which in turn provides control to and from the subsystem controls. FIG. 19 provides a functional overview of how the various levels of control may be distributed. The embodiment of control system 1800 shown in FIG. 19 is not meant to be all-inclusive, simply an indication of a potential control system for controlling system 1600. It should be understood, although it is not implicit, that although the focus of the invention record is on an atmospheric plasma microwave system, it can also operate as a standard microwave system as well. In that sense, it can be construed as a “Hybrid System”. An example would be to activate adhesives that require an external heat source to begin the curing process (exothermic reaction) such as in bonding composites. Additionally, any application that requires microwave energy is also a candidate such as: rubber vulcanizing, grain drying, powder drying and the like.

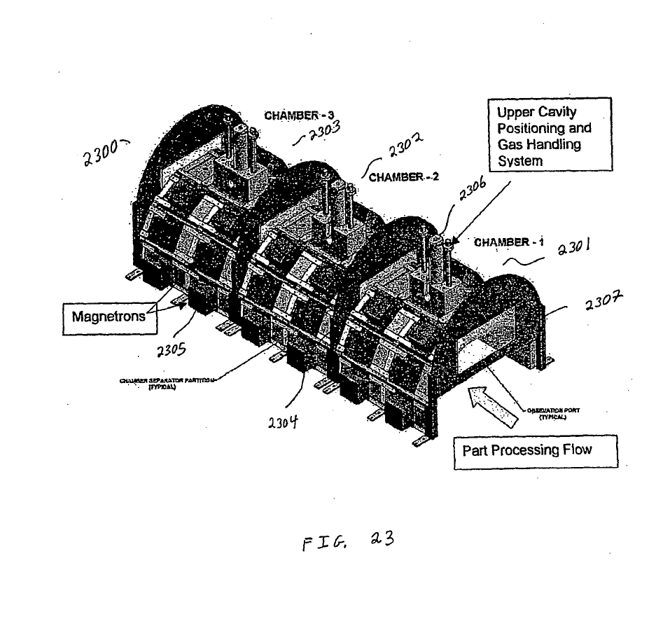

FIG. 21 illustrates a magnetron tunnel system 2100 according to some embodiments of the present invention. A large number of magnetrons 2102 are arranged around a belt fed processing line 2103. Parts can be processed as they are transported along line 2103. Once processed, parts can be transported to another station.

Another multi-chamber system can employ the lazy-Susan concept discussed with respect to FIG. 10 above. Parts 320 are passed into the lazy Susan 310 via air locks for gas containment. The part carriers are positioned or indexed around the table as the cycle proceeds. The part carrier is raised up into the microwave horn, which forms the other half of the cavity that will contain the plasma for part processing. Subsequent stations can be utilized simply for cool down portions of the processing cycle. The system shown in FIG. 10 offers several flexible features. First, although only a single magnetron is shown in FIG. 10, multiple magnetrons can be utilized. Second, although only a single processing station is shown, multiple stations can be included. Each station can include its own magnetron and, in fact, can be performing different functions on the parts being processed. For example, in a powder metal sintering process, one station can perform a de-lubrication of the green part, a second station can perform the sintering, and a third station can perform a surface process, and the part can be cooled in a fourth station.

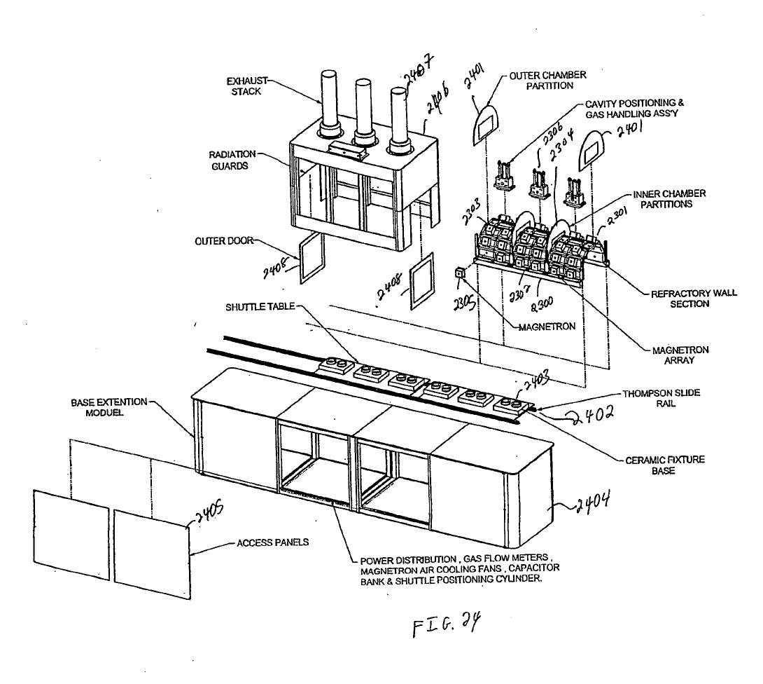

FIGS. 22-24 illustrates another multi-chamber system 2200 according to the present invention. As shown in FIG. 23, multi-chamber system 2200 can include a reactor system 2300 with multiple reactors. In FIG. 23, reactors 2301, 2302, and 2303 are shown. Each of reactors 2301, 2302, and 2303 can include multiple magnetrons arranged around the perimeter of the half-cylinder. Reactors 2301, 2302, and 2303 can be separated by partitions 2304 that keeps each of reactors 2301, 2302, and 2303 separated from the other reactors. A positioning and gas handling system 2306 can be attached to each reactor 2301, 2302, and 2303 in order to supply gas, provide exhaust, and position a cavity in each of reactors 2301, 2302, and 2303. Each of reactors 2301, 2302, and 2303 can be identical, or can be tailored to perform a particular process. In chamber 2301, 12 magnetrons 2305 are shown. If each of the 12 magnetrons is rated at, for example, 1.5 kW, then a total of 54 kW can be utilized in providing a plasma.

As shown in FIG. 23, each chamber partition 2304 can be individually controlled. This minimizes potential cross talk between the various chambers. Further, partitions 2304 can remain up to allow for larger part geometries. As shown in FIG. 23, reactors 2301, 2302, and 2303 can be of any size and each can include any number of individual magnetrons 2305.

As shown in FIG. 22, a control system 2201 can provide precise gas flow handling to handling systems 2306 of each chamber in order to control the process being performed in each chamber. Control system 2201 controls both gas flow and gas mixture to each of reactors 2301, 2302, and 2303. In some embodiments, control system 2201 can control the exhaust system as well.

FIG. 24 illustrates system 2200. As shown in FIG. 24, outer chamber partitions 2401 can completely close off reactors 2301 and 2303. Further, instead of utilizing a belt system as is shown in FIG. 21, a rail system 2402 can be utilized to transport parts between reactors. Parts 2403 can be transported into each chamber and, in some embodiments, parts carriers can form part of a cavity when positioned in reactors 2301, 2302, and 2303. Lower cabinet assembly 2404 houses microwave power components, gas manifolds, flow control valves, cooling, power connections, and all other components for operating system 2200. Other housing 2406 provides exhaust vents 2407 as well as outer doors 2408 and radiation guards. Although three reactors are shown, any number of reactors can be utilized.

In general, any system to perform a manufacturing process has its own set of unique parameters that are controlled to achieve optimum results. In some embodiments, single plasma processing chambers can be intermingled with other processing stations in order to perform a complete manufacturing processes. Extremely high operating temperatures can be attained very quickly in processes according to the present invention.

Containment materials for parts, therefore, should withstand the thermal shock of rapid heating and extended high temperature soaks. Further, such materials should be capable of cycling many times. Ceramic or refractory materials may be suited for this task.

In the foregoing described embodiments, various features are grouped together in a single embodiment for purposes of streamlining the disclosure. This method of disclosure is not to be interpreted as reflecting an intention that the claimed invention requires more features than are expressly recited in each claim. Rather, as the following claims reflect, inventive aspects lie in less than all features of a single foregoing disclosed embodiment. Thus, the following claims are hereby incorporated into this Detailed Description of Embodiments, with each claim standing on its own as a separate preferred embodiment of the invention.

We claim:

1. A method of plasma-assisted processing a plurality of work pieces, the method comprising:
placing each of the plurality of work pieces in a plurality of movable carriers;
moving a first subset of movable carriers into a first irradiation zone with a conveyance system;
flowing a gas into the first irradiation zone;
igniting the gas in the first irradiation zone to form a first plasma;
sustaining the first plasma for a period of time sufficient to at least partially plasma process work pieces in the first subset of movable carriers in the first irradiation zone;
removing the first subset of movable carriers out of the first irradiation zone with the conveyance system;
moving a second subset of movable carriers into a second irradiation zone with the conveyance system; and
processing the second subset of movable carriers with a second plasma ignited in the second irradiation zone.

2. The method of claim 1, wherein the first subset of movable carriers is processed in the first irradiation zone concurrently with processing the second subset of movable carriers in the second irradiation zone.

3. The method of claim 1, wherein the first subset of movable carriers is identical with the second subset of movable carriers.

4. The method of claim 1, wherein the plasma-processing is at least one of sintering, annealing, normalizing, spheroiding, tempering, age hardening, case hardening, joining, doping, nitriding, carburizing, decrystallizing, carbo-nitriding, cleaning, sterilizing, vaporizing, coating and ashing.

5. The method of claim 1, wherein the conveyance system comprises at least one of a belt, a track, a robot, a turntable, a roller, a wheel, a chain, a bucket, a tray, a guide rail, a lift, a screw, a push bar, a ribbon screw, a rail system, an under floor system, a roller system, a slider system, a slat system, a gravity feed system, a chain on edge system, a cable system, a magnetic conveyor, a pulley system, a reciprocating conveyor, and any other mechanism capable of moving the work pieces from one location to another.

6. The method of claim 1 wherein the work piece includes at least one of a metal, a non-metal, a ceramic, a glass, an organic material, and a non-organic material.

7. The method of claim 1, wherein the first irradiation zone includes a housing for adjoining the carrier.

8. The method of claim 7, wherein the housing and the carrier cooperate to form a cavity.

9. The method of claim 7, wherein the second irradiation zone includes a housing for adjoining the carrier, the housing and the carrier forming a second cavity.

10. The method of claim 1, further comprising igniting the plasma in the first irradiation zone using a plasma catalyst.

11. The method of claim 10, wherein the catalyst comprises at least one of metal, inorganic material, carbon, carbon-based alloy, carbon-based composite, electrically conductive polymer, conductive silicone elastomer, polymer nanocomposite, and an organic-inorganic composite.

12. The method of claim 11, wherein the catalyst is in the form of at least one of a nano-particle, a nano-tube, a powder, a dust, a flake, a fiber, a sheet, a needle, a thread, a strand, a filament, a yarn, a twine, a shaving, a sliver, a chip, a woven fabric, a tape, and a whisker.

13. The method of claim 1, wherein radiation is directed to the first irradiation zone with a waveguide.

14. The method of claim 1, wherein a process performed in the first irradiation zone is different from a process performed in the second irradiation zone.

15. An apparatus for plasma-assisted processing a plurality of work pieces, the apparatus comprising:
a first chamber, the first chamber coupled to receive a gas flow and radiation in order to ignite a first plasma within the first chamber;
a second chamber, the second chamber coupled to receive a gas flow and radiation in order to ignite a second plasma within the second chamber; and
a conveyance system coupled to shuttle work pieces in and out of each of the first chamber and the second chamber.

16. The apparatus of claim 15, wherein the first chamber is coupled to one or more magnetrons to provide microwave radiation.

17. The apparatus of claim 16, wherein the second chamber is coupled to one or more magnetrons to provide microwave radiation.

18. The apparatus of claim 15, further including a number of further chambers coupled by the conveyance system to receive and process work pieces.

19. The apparatus of claim 15, wherein the work pieces are carried by carriers.

20. The apparatus of claim 19, wherein the carriers form a portion of a cavity in each of the first chamber and the second chamber during processing of the work piece.

21. The apparatus of claim 15, wherein the conveyance system includes rollers or conveyor belts.

22. The apparatus of claim 15, wherein the conveyance system includes a slide rail.

23. The apparatus of claim 15, further including sensors to determine when the work piece is properly positioned within one of the first chamber or the second chamber.

24. The apparatus of claim 15, wherein one of the first chamber or the second chamber includes microwave absorbers positioned to direct microwave energy to a plasma.

25. The apparatus of claim 15, wherein one of the first chamber or the second chamber includes a first and a second cavity area for processing of multiple parts.

26. The apparatus of claim 15, further including a number of buffer chambers for cooling or processing parts outside of the first and second chambers.

27. A reactor, comprising:
a chamber coupled to receive microwave energy and gas flow;
a cavity positioned in the chamber, and
microwave absorbers positioned within the chamber to maximize microwave energy in the cavity, wherein
a plasma can be ignited in the cavity in the presence of the gas and the microwave energy.

28. A reactor, comprising
a chamber coupled to receive microwave energy and gas flow;
a first cavity positioned in the chamber, and
a second cavity positioned in the chamber, wherein
a plasma can be ignited in both the first cavity and the second cavity in the presence of the gas and the microwave energy.
